(19) United States
(12) Patent Application Publication
(10) Pub. No.: US 2020/0187349 A1
(43) Pub. Date: Jun. 11, 2020

(54) METHODS AND SYSTEMS FOR CONNECTING A POWER SOURCE TO MOBILE DEVICES

(71) Applicant: MC10, Inc., Lexington, MA (US)

(72) Inventors: Stephen LEE, Ann Arbor, MI (US); Nicholas KUBASTI, Seattle, WA (US); Scott SHAW, Waltham, MA (US); David GARLOCK, Derry, NH (US); Gregory LEVESQUE, Holden, MA (US); Adam LEECH, Newton, MA (US); Steven FASTERT, Chelmsford, MA (US); Jeffrey MODEL, Cambridge, MA (US)

(73) Assignee: MC10, Inc., Lexington, MA (US)

(21) Appl. No.: 16/334,609

(22) PCT Filed: Sep. 22, 2017
(86) PCT No.: PCT/US17/52982

§ 371 Date: Mar. 19, 2019

Related U.S. Application Data
(60) Provisional application No. 62/398,721, filed on Sep. 23, 2016.

(51) Int. Cl. H05K 1/02; H05K 1/18

(52) U.S. Cl. CPC H05K 1/0286; H05K 1/189; H05K 2201/10083; H05K 2201/10053; H05K 2201/10037

(57) ABSTRACT

A mobile device includes one or more electronic circuits that control the operation of the device. The electronic circuit can be connected to a power source by a switch that can be maintained in the open position when the device is being shipped and stored prior to use. The act of taking the mobile device out of the package can include manipulating the mobile device to cause the switch to close connecting the electronic circuit to the power source to begin operation. In accordance with some embodiments, the switch can include a magnetic switch that is maintained in the open position by a magnetic component in the packaging and becomes closed when the mobile device is removed from the packaging. In accordance with some embodiments, the switch can be maintained in the open position by a packaging insert and becomes closed when the package is opened removing the insert.

### CROSS-REFERENCE TO RELATED APPLICATIONS

The present application claims the benefit of and priority to U.S. Provisional Application No. 62/398,721 filed Sep. 23, 2016, entitled, “METHODS AND SYSTEMS FOR CONNECTING A POWER SOURCE TO MOBILE DEVICES,” which is hereby incorporated by reference herein in its entirety.

### BACKGROUND

### Technical Field of the Invention

The present invention is directed to methods and systems for controlling the connection of a power source, such as a battery, to a mobile device in order to maintain the charge in the battery during shipping and storage prior to use. More specifically, the invention is directed to methods and systems for disconnecting the battery from the electronic circuit in the mobile device until the package is opened and providing a convenient means for connecting the battery to the electronic circuit in the mobile device so it can power up with a fresh battery.

### Description of the Prior Art

Portable and mobile electronic devices typically include a power source, such as a battery, that is used to power the device during use. In many devices, the battery is connected to the circuitry in the portable device and through the momentary contact of a switch, the device is powered on. One disadvantage of this configuration is that the battery is used to power a small power-on circuit and as a result, this limits the shelf life of the device because the circuit draws power from the battery.

For some devices, a simple on-off switch could be employed, but for smaller and flexible devices, the use of even the smallest mechanical switch can be impractical. In addition, small switches can be a challenge for older users and visually impaired users.

In some devices, an insulating sheet is positioned between the battery and one of the battery contacts. The insulating sheet includes a pull-tab that the user can pull to make the connection between the battery and the circuit. Manipulating the pull tab can be a challenge for older users and some physically or visually impaired users. In addition, this is not an option for devices that are sealed to the elements as there needs to be a space to insert the pull-tab during manufacture and that space remains open after the pull-tab is removed.

### SUMMARY

The present invention is directed to methods and systems for controlling the connection between a power source, such as a battery, and the electronic circuit that controls the operation of a mobile electronic device. In accordance with some embodiments of the invention, the mobile device can be manufactured (e.g., assembled and tested) with the power source connected. After testing is completed, the power source can be fully charged and disconnected from the electronic circuit in the mobile device prior to being packaged for shipment and storage. Because the battery is disconnected from the circuit, the charge in the battery can be preserved during shipment and storage, thus providing a longer shelf-life than prior art systems. Depending on the size and configuration of the device, a form of a switch can be provided that connects the electronic circuit to the power source to power the device during use. In accordance with some embodiments of the invention, the switch can be manipulated from the open position (e.g., disconnecting the power source) to the closed position connecting the electronic circuit to the power source to power the mobile device.

In accordance with some embodiments of the invention, the mobile device can include an adhesive layer that enables the mobile device to be adhered, for example, to the skin of a user. The mobile device can be packaged with protective packaging that includes a liner that protects the adhesive layer during shipment and storage. The mobile device can include an electronic circuit that controls the operation of the device including, for example, a computer microprocessor and associated memory, and one or more sensors or actuators or radios or information display elements (e.g., a display screen, alpha numerical display or individual lights). The mobile device can include a power source, such as a rechargeable battery that is connected to the electronic circuit by a magnetic switch that is normally closed and opens in the presence of the magnet field. The liner can include a magnetic component that is positioned such that when the liner is in position covering the adhesive layer, the magnetic field is positioned sufficiently adjacent the magnetic switch to maintain the magnetic switch in an open position. When the liner is removed by the user, the magnetic component (and the magnetic field) is moved away from the magnetic switch causing the magnetic switch to close connecting the power source to the electronic circuit.

In accordance with some embodiments of the invention, the mobile device can include an adhesive layer that enables the mobile device to be adhered, for example, to the skin of a user. The mobile device can be packaged with protective packaging that includes a liner that protects the adhesive layer during shipment and storage. The mobile device can include an electronic circuit that controls the operation of the device including, for example, a computer microprocessor and associated memory, and one or more sensors or actuators or radios or information display elements (e.g., a display screen, alpha numerical display or individual lights). The mobile device can include a power source, such as a rechargeable battery, that is connected to the electronic circuit by a set of contacts that is normally closed. The contacts can be configured to allow an insulating sheet or pin to be inserted between them to open the contacts and disconnect the power source from the electronic circuit. The insulating sheet or pin can be connected to the liner such that when the liner is removed by the user, the insulating sheet or pin is removed as well causing the contacts to close connecting the power source to the electronic circuit.

In accordance with some embodiments of the invention, the mobile device can be sealed inside a package that protects the device from the elements and, for example, maintain the device in a fresh or sterile state until opened. The package can also protect the device during shipment and storage. The mobile device can include an electronic circuit that controls the operation of the device including, for example, a computer microprocessor and associated memory, and one or more sensors or actuators or radios or information display elements (e.g., a display screen, alpha numerical display or individual lights). The mobile device can include a power source, such as a rechargeable battery that is connected to the electronic circuit by an optical switch that is open when placed in a dark environment and closes to connect the power source to the electronic circuit when exposed to light. The packaging can be opaque such that when the mobile device is enclosed in the packaging the optical switch is not exposed to light and maintains the switch in the open position whereby the power source is disconnected from the electronic circuit. When the user opens the package, the optical switch becomes exposed to light and closes the switch connecting the electronic circuit to the power source. A relay or latch can be provided, such that once the optical switch is closed, the relay or latch maintains the connection between the power source and the electronic circuit in the event the device is placed in a dark environment (e.g., at night or covered by clothing).

In accordance with some embodiments of the invention, the mobile device can be sealed inside a package that protects the device from the elements and, for example, maintain the device in a fresh or sterile state until opened. The package can also protect the device during shipment and storage. The mobile device can include an electronic circuit that controls the operation of the device including, for example, a computer microprocessor and associated memory, and one or more sensors or actuators or radios or information display elements (e.g., a display screen, alpha numerical display or individual lights). The mobile device can include a power source, such as a rechargeable battery, that is connected to the electronic circuit by a mechanical switch that is normally closed but can be opened by the application of pressure on one of the contacts. The packaging can be evacuated (e.g., vacuum sealed) such that when the mobile device is enclosed in the packaging, the packaging or a packaging insert applies pressure on the mechanical switch and maintains the switch in the open position whereby the power source is disconnected from the electronic circuit. When the user opens the package, the pressure inside the package equalizes and the insert no longer applies pressure on the switch and the switch returns to the closed position connecting the electronic circuit to the power source. The switch can be enclosed by a housing such that the insert can apply pressure on the switch but when the insert is removed, under normal use conditions, the housing prevents or limits the ability of a foreign object from applying pressure to the switch. Alternatively, a relay or latch can be provided, such that once the mechanical switch is closed, the relay or latch maintains the connection between the power source and the electronic circuit in the event a foreign object inadvertently applies pressure on the switch.

In accordance with some embodiments of the invention, the mobile device can include an electronic circuit that controls the operation of the device include, for example, a computer microprocessor and associated memory, and one or more sensors or actuators or radios or information display elements (e.g., a display screen, alpha numerical display or individual lights). The mobile device can include a power source, such as a rechargeable battery, that is connected to the electronic circuit by a mechanical switch that is moveable between an open position and a closed position. The mechanical switch can be restrained in the open position by one or more pins and/or tabs that maintain the switch in the open position until a predefined amount of force or pressure is applied to the switch to move the switch contact past the pins or tabs to be maintained in contact against the other switch contact in the closed position. In accordance with some embodiments, one or more of the pins or tabs can bend or break off when pressure is applied. The switch can be embedded within the encapsulating material of the mobile device. A pressure plate or other element in the encapsulating material or between the encapsulating material and the switch can be provided to focus the application of pressure by the user to enable the switch contact to be moved into the closed position. The same tabs or additional tabs or a latching mechanism can be provided to maintain the switch contact in the closed position.

In accordance with some embodiments of the invention, the mobile device can be sealed inside a package that protects the device from the elements and, for example, maintain the device in a fresh or sterile state until opened. The package can include a stiffener that also protects the device during shipment and storage and prevents the device from being bent or twisted inside the package. The mobile device can include an electronic circuit that controls the operation of the device including, for example, a computer microprocessor and associated memory, and one or more sensors or actuators or radios or information display elements (e.g., a display screen, alpha numerical display or individual lights). The mobile device can include a power source, such as a rechargeable battery, that is connected to the electronic circuit by a relay or solid-state switch that is open and closes to connect the power source to the electronic circuit when an electrical charge is received by the switch. The mobile device can be flexible and/or stretchable and include a piezo-electric material layer that generates a charge or a current that is coupled to the relay or switch, such that bending and/or twisting the mobile device causes a charge to be delivered to the switch that closes the switch and connects the electronic circuit to the power source. The packaging can include a stiffener that prevents the mobile device from being bent and/or twisted such that when the mobile device is enclosed in the packaging the piezoelectric material layer cannot be bent or twisted sufficiently to produce enough charge or current to close the switch and thereby maintains the switch in the open position and keeps the power source disconnected from the electronic circuit. Prior to use, the user removes the mobile device from the package and bends and/or twists the mobile device sufficiently to cause the piezoelectric material to produce enough charge or current to the switch connecting the electronic circuit to the power source. A relay or latch can be provided, such that once the switch is closed, the relay or latch maintains the connection between the power source and the electronic circuit even though the piezoelectric material has stopped generating a charge or current to close the switch.

In accordance with some embodiments of the invention, the mobile device can include a by-pass circuit that enables the device to be powered for manufacturing and testing purposes that enables the switch to be maintained in the open position in the final stages of manufacturing, and during packaging and shipping. For example, the electronic circuit can include contacts for an external power source to power the device during test that can be disconnected and removed prior to encapsulation. Alternatively, the electronic circuit can include an induction coil that enables the circuit to be powered by an electromagnetic field for testing after encapsulation, as well as for charging the power source (e.g., battery) during normal use.

These and other capabilities of the invention, along with the invention itself, will be more fully understood after a review of the following figures, detailed description, and claims.

### BRIEF DESCRIPTION OF THE FIGURES

The accompanying drawings, which are incorporated into this specification, illustrate one or more exemplary embodiments of the inventions and, together with the detailed description, serve to explain the principles and applications of these inventions. The drawings and detailed description are illustrative, and are intended to facilitate an understanding of the inventions and their application without limiting the scope of the invention. The illustrative embodiments can be modified and adapted without departing from the spirit and scope of the inventions.

FIGS. 1A and 1B show block diagrams of a mobile device having a magnetically controlled switch according to some embodiments of the invention.

FIGS. 2A and 2B show block diagrams of a mobile device having a mechanically controlled switch according to some embodiments of the invention.

FIGS. 3A and 3B show block diagrams of a mobile device having an optically controlled switch according to some embodiments of the invention.

FIGS. 4A and 4B show block diagrams of a mobile device having a resettable mechanical switch according to some embodiments of the invention.

FIGS. 5A and 5B show block diagrams of a mobile device having a resettable mechanical switch according to some embodiments of the invention.

FIGS. 6A, 6B and 6C show block diagrams of a mobile device having a mechanical switch according to some embodiments of the invention.

FIGS. 7A and 7B show block diagrams of a mobile device having a pressure controlled switch according to some embodiments of the invention.

FIGS. 8A and 8B show block diagrams of a mobile device having a piezoelectric layer operated switch according to some embodiments of the invention.

FIGS. 9A and 9b show block diagrams of a latching circuit according to some embodiments of the invention.

### DETAILED DESCRIPTION OF PREFERRED EMBODIMENTS

The present invention is directed to methods and systems for controlling the application of power (e.g. electricity) to the electronic circuits in mobile devices. During assembly and testing of the mobile device up to the point at which the mobile device is placed in the package for shipping, the device needs to be powered for testing and configuration. However, after the mobile device is placed in its package for shipping and storage, the internal power source (e.g., battery) should be disconnected to maintain a long shelf life of the power source. Further, the mobile device can provide a convenient way for the user to connect the electronic circuit to the power source after the user removes the device from the package.

In accordance with some embodiments of the invention, the mobile device includes one or more electronic circuits connected to one or more power sources by a power controlling device such as, for example, a switch, that enables at least one of the electronic circuits to be disconnected from its power source to prevent the power source from being drained during packaging, shipping and storage. The electronic circuit that controls the operation of the mobile device can include, for example, a computer microprocessor and associated memory, and one or more sensors or actuators or radios or information display elements (e.g., a display screen, alpha numerical display or individual lights). In accordance with some embodiments of the invention, the switch can be embedded or encapsulated in the device to protect it from the elements and as a result of an act consistent with removing the packaging or applying the device to the body, cause the switch to close. In accordance with some embodiments of the invention, the mobile device can further include a mechanism that enables the user to close the switch when the device is removed from the packaging to enable operation of the mobile device.

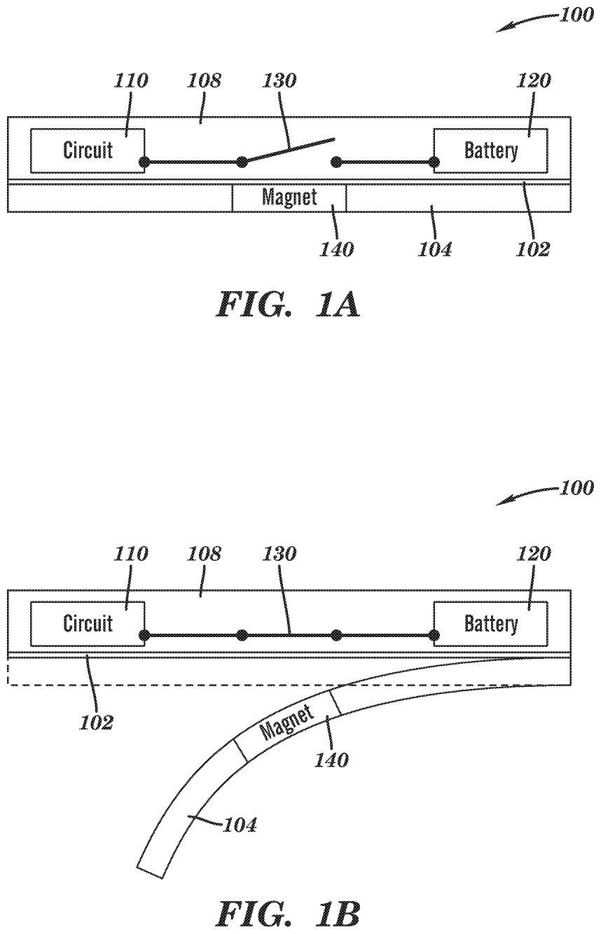

FIGS. 1A and 1B show diagrammatic views of a mobile device 100 in accordance with some embodiments of the invention. The mobile device 100 can include an electronic circuit 110 connected to a power source 120 (e.g., a battery) by a magnetic switch 130. The electronic circuit 110 that controls the operation of the mobile device 100 can include, for example, a computer microprocessor and associated memory, and one or more sensors or actuators or radios or information display elements (e.g., a display screen, alpha numerical display or individual lights). The mobile device 100 can also include one or more encapsulation layers or a housing or enclosure 108. The mobile device 100 can further include an adhesive layer 102 that can be used to adhere the device to a surface, such as the surface of an object or the skin of a person or animal. To protect the adhesive layer 102 prior to use, the mobile device 100 can include a liner 104 that covers the adhesive layer 102 while the mobile device 100 is in its packaging. The liner 104 can further include a magnet (or magnetic material) 140 that is positioned adjacent to the magnetic switch 130 such that when the liner 104 is in position on the adhesive layer, the magnetic switch 130 is exposed to the magnet field of the magnet 140 sufficient to maintain the magnetic switch 130 in the open position. In accordance with some embodiments of the invention, the switch 130 can be a normally closed magnetic reed switch that becomes open in the presence of a magnetic field. In accordance with some embodiments of the invention, a latching circuit can be provided, such that once the switch 130 is closed, the latching circuit maintains the connection between the power source and the electronic circuit in the event the device is placed near a magnetic field strong enough to open the switch 130.

In operation, the mobile device 100 can be packaged in a sealed package for shipment and storage. To prepare the device for use, the user opens the package and removes the device 100. Prior to applying the mobile device 100 to the skin, for example, the user removes the liner 104 to expose the adhesive layer 102. Upon removing the liner 104, magnet 140 (and the associated magnetic field) is moved away from the magnetic switch 130 and the magnetic switch 130 becomes closed, connecting the electronic circuit 110 to the power source 120 to begin operation as shown in FIG. 1B.

During assembly and test, and prior to encapsulation (e.g., enclosure in a housing or encapsulating layer 108), the mobile device 100 can be supported by fixture that does not include a magnet or magnetic element 140 positioned adjacent the magnetic switch 130, such that the magnetic switch is closed supplying power to the electronic circuit 110. Prior to removal from the support fixture, the power source 120 can be charged and the adhesive layer 102 along with the liner 104 with magnetic element 140 can be applied to open the magnetic switch 130 to prepare the device for packaging and shipping. When the adhesive layer 102 and the liner 104 is applied, the magnetic element 140 applies a magnetic field to the magnetic switch 130, opening the switch and disconnecting the power source 120 from the electronic circuit 110 in preparation for packaging, shipment and storage.

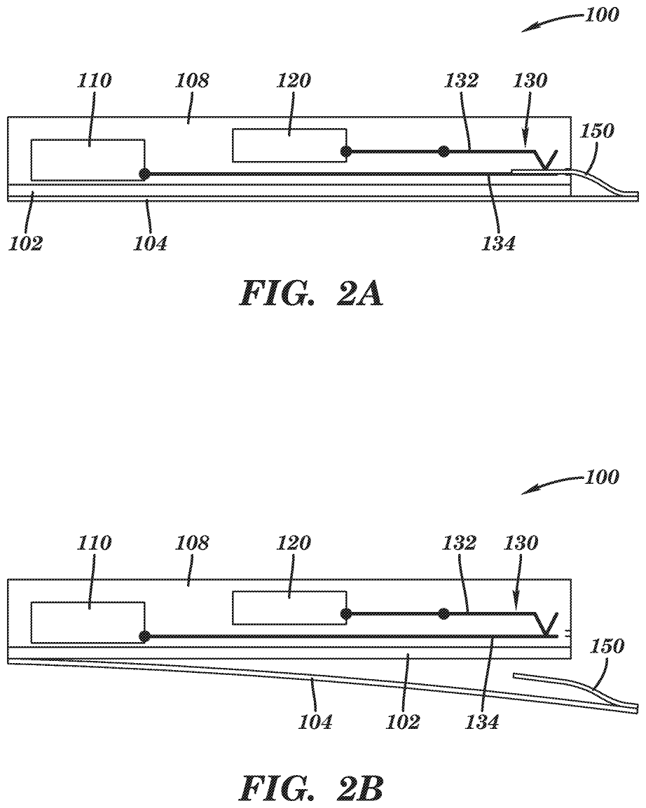

FIGS. 2A and 2B show diagrammatic views of a mobile device 100 in accordance with some embodiments of the invention. The mobile device 100 can include a circuit 110 connected to a power source 120 (e.g., a battery) by a switch formed by a set of mechanical contacts 130. The electronic circuit 110 that controls the operation of the mobile device 100 can include, for example, a computer microprocessor and associated memory, and one or more sensors or actuators or radios or information display elements (e.g., a display screen, alpha numerical display or individual lights). The mobile device 100 can also include one or more encapsulation layers or a housing or enclosure 108. The mobile device 100 can further include an adhesive layer 102 that can be used to adhere the device to a surface, such as the surface of an object or the skin of a person or animal. To protect the adhesive layer 102 prior to use, the mobile device 100 can include a liner 104 that covers the adhesive layer 102 while the mobile device 100 is in its packaging. The liner 104 can further include a flap or tab 150 (e.g., an insulating material such as Mylar or polyimide) that is positioned between the contacts 130 such that when the liner 104 is in position on the adhesive layer, the flap or tab 150 is held in position between the contacts to maintain the contacts 130 in the open position. In accordance with some embodiments of the invention, the contacts 130 can include a moveable contact 132 that is flexible and biased (e.g., such as by a spring force or its own shape and flexibility) be in a normally closed position against the stationary contact 134 to electrically connect the electronic circuit 110 to the power source 120. In accordance with some embodiments of the invention, a latching circuit can be provided, such that once the contacts 130 are closed, the latching circuit maintains the connection between the power source and the electronic circuit in the event the device is used in a high vibration environment.

In operation, the mobile device 100 can be packaged in a sealed package for shipment and storage. To prepare the device for use, the user opens the package and removes the device 100. Prior to applying the mobile device 100 to the skin, for example, the user removes the liner 104 to expose the adhesive layer 102. Upon removing the liner 104, the tab or flap 150 is removed from between the contacts of the switch 130 and the switch 130 becomes closed, connecting the electronic circuit 110 to the power source 120 to begin operation as shown in FIG. 2B.

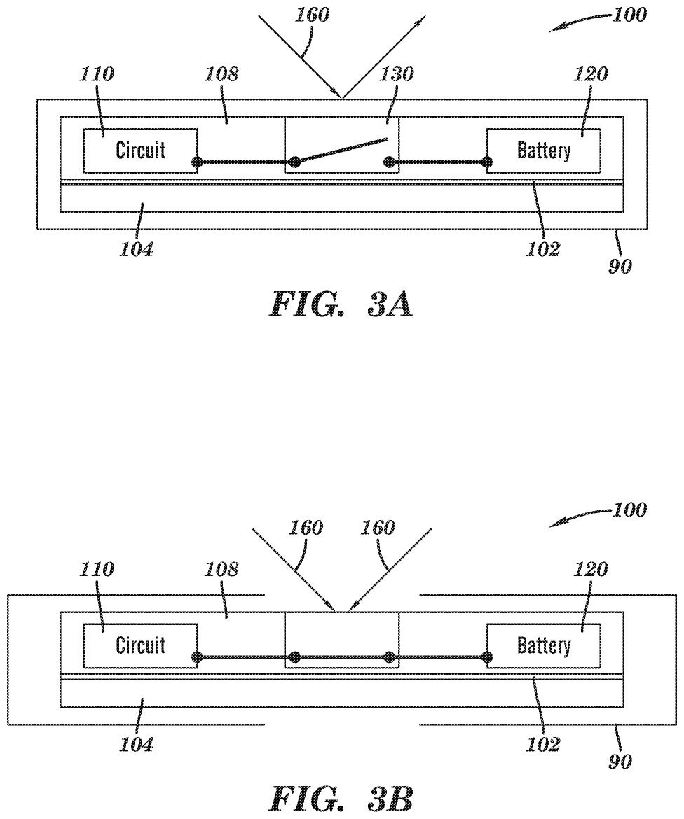

FIGS. 3A and 3B show diagrammatic views of a mobile device 100 in accordance with some embodiments of the invention. The mobile device 100 includes a circuit 110 connected to a power source 120 (e.g., a battery) by an optical switch 130. The electronic circuit 110 that controls the operation of the mobile device can include, for example, a computer microprocessor and associated memory, and one or more sensors or actuators or radios or information display elements (e.g., a display screen, alpha numerical display or individual lights). The mobile device 100 can also include one or more encapsulation layers or a housing or enclosure 108. The mobile device 100 can further include an adhesive layer 102 that can be used to adhere the device to a surface, such as the surface of an object or the skin of a person or animal. To protect the adhesive layer 102 prior to use, the mobile device 100 can include a liner 104 that covers the adhesive layer 102 while the mobile device 100 is in its packaging 90. The packaging can be fully opaque or opaque in a portion that covers the optical sensor of the optical switch 130. When the mobile device 100 is positioned inside the packaging 90, the opaque material or portion of the packaging 90 covers the optical switch 130, blocking it from the light and causing the switch 130 to be maintained in the open position (and keeping the electronic circuit 110 disconnected from the power source 120). In accordance with some embodiments of the invention, the optical switch 130 can be closed when exposed to light and becomes open when covered (e.g., light is blocked from activating the optical sensor). In accordance with some embodiments of the invention, a latching circuit can be provided, such that once the optical switch 130 is closed, the latching circuit maintains the connection between the power source and the electronic circuit in the event the device is placed in a dark environment (e.g., at night or covered by clothing).

In operation, the mobile device 100 can be packaged in a sealed package for shipment and storage. To prepare the device for use, the user opens the package and removes the device 100. Upon removal of the device from the opaque packaging, the optical switch 130 is exposed to the ambient light of the environment causing it to close and connect the electronic circuit 110 to the power source 120 to begin operation as shown in FIG. 3B.

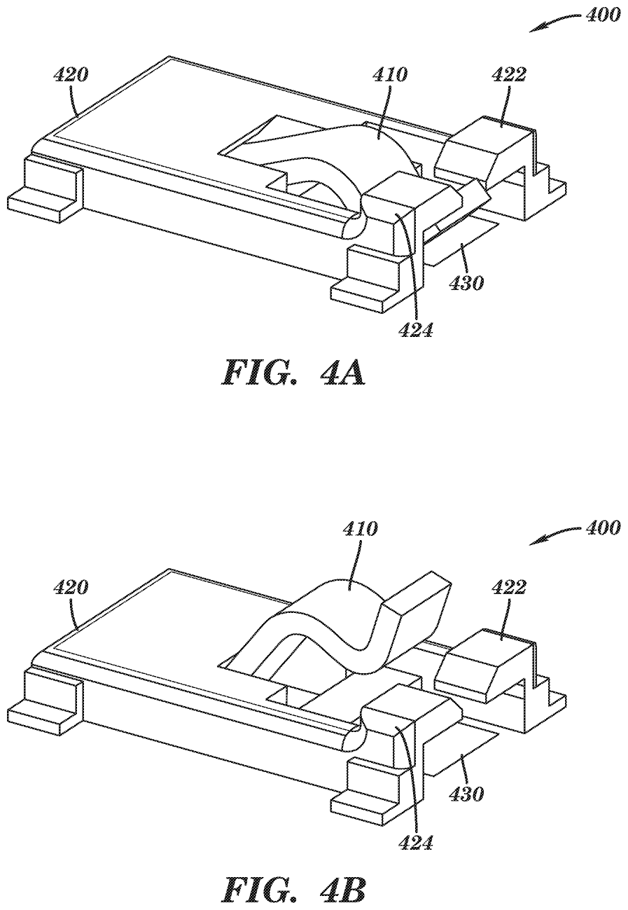

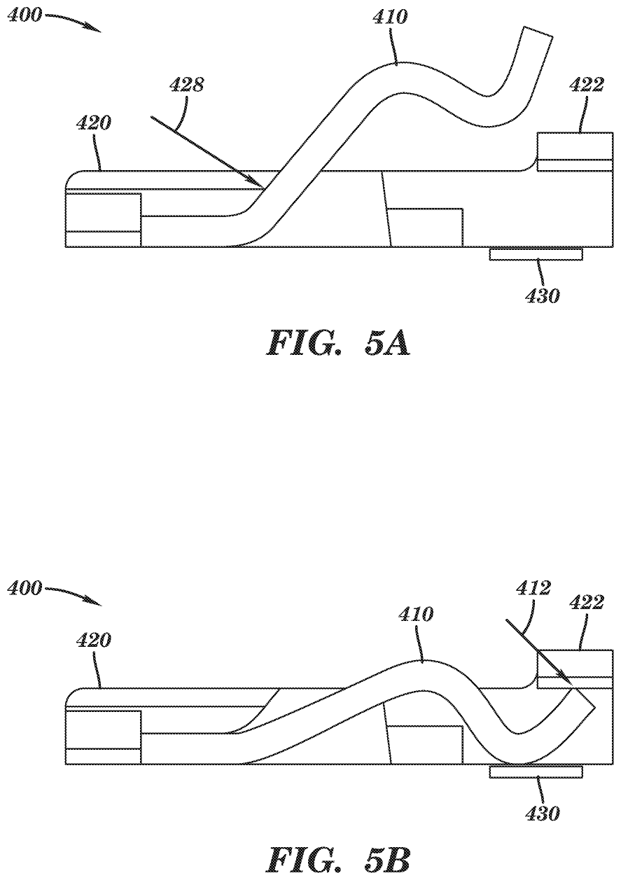

FIGS. 4A and 4B show diagrammatic isometric views and FIGS. 5A and 5B show diagrammatic cross-sectional views of a mechanical switch 400 can that can be used in a mobile device 100, such as that shown in FIGS. 1A, 1B, 2A, 2B and 3A, 3B according to some embodiments of the invention. The mechanical switch 400 can be installed to connect the electronic circuit 110 to the power source 120 of the mobile device 100. The mechanical switch 400 can include a moveable contact 410 that can be moved between an open position (e.g., shown in FIGS. 4B and 5A) and the closed position (e.g., shown in FIGS. 4A and 5B), and a stationary contact 430 that can be positioned under or adjacent to the moveable contact 410 such that an electrical connection is made when the moveable contact 410 is moved into the closed position. One of the moveable contact 410 and the stationary contact 430 can be connected to the power source 120 and the other of the moveable contact 410 and the stationary contact 430 can be connected to the electronic circuit 110. The mechanical switch 400 can further include a housing 420 that can include one or more flexible tabs 422, 424, that prevent the moveable contact 410 from coming in contact with the stationary contact 430 unless a force is applied to manipulate the moveable contact 410 past the flexible tabs 422 and 424 and hold the moveable contact 410 in position against the stationary contact 430 to close the electrical connection.

In operation, after assembly and test, the mobile device 100 can be packaged with the moveable contact 410 in the open position maintaining the electronic circuit 110 disconnected from the power source 120. When the user desires to use the mobile device 100, the user can apply a force with their finger or blunt object (e.g., a stylus or pen tip) to push the moveable contact 410 between the flexible tabs 422 and 424 into the closed position, connecting the electronic circuit 110 to the power source 120.

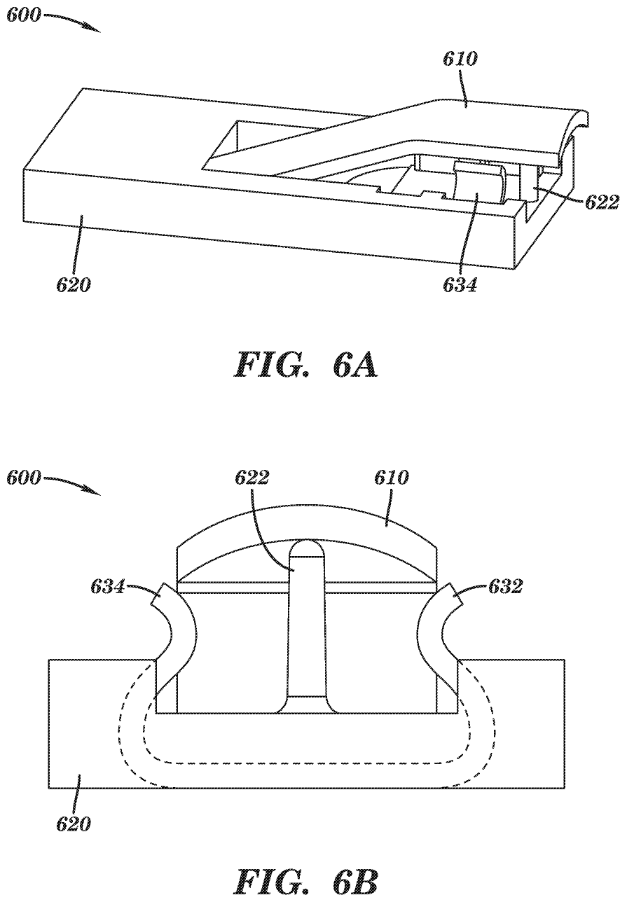

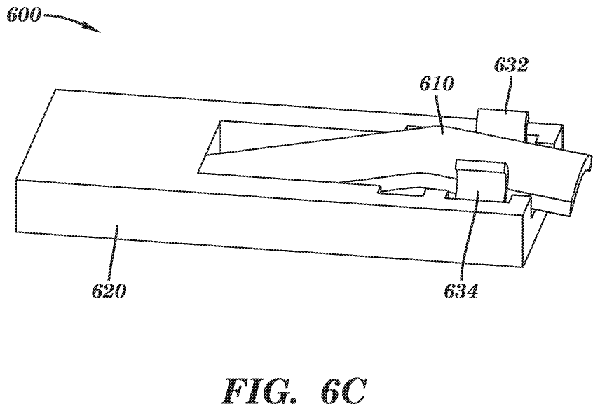

FIGS. 6A, 6B and 6C show diagrammatic views of a mechanical switch 600 can that can be used in a mobile device 100, such as that shown in FIGS. 1A, 1B, 2A, 2B and 3A, 3B according to some embodiments of the invention. The mechanical switch 600 can be installed to connect the electronic circuit 110 to the power source 120 of the mobile device 100. The mechanical switch 600 can include a moveable contact 610 that can be moved between an open position (e.g., shown in FIGS. 6A and 6B) and the closed position (e.g., shown in FIG. 6C), and a stationary contact 630 that can be positioned under or adjacent to the moveable contact 610 such that an electrical connection is made when the moveable contact 610 is moved into the closed position. One of the moveable contact 610 and the stationary contact 630 can be connected to the power source 120 and the other of the moveable contact 610 and the stationary contact 630 can be connected to the electronic circuit 110. The mechanical switch 600 can further include a housing 620 that can include one or more restraining pins or tabs 622 that prevent the moveable contact 610 from coming in contact with the stationary contact 630 unless a force is applied to manipulate the moveable contact 610 to displace (e.g., bend or break) at least one of the restraining pins or tabs 622 and enabling the moveable contact 610 to move into position against the stationary contact 630 to close the electrical circuit and make the electrical connection between the electronic circuit 110 and the power source 120. In accordance with some embodiments of the invention, the stationary contact 630 can include two tabs 632 and 634 that engage (e.g., surround or capture) the moveable contact 610 after the restraining pins or tabs 622 are displaced and maintain the connection between the electronic circuit 110 and the power source 120.

In operation, after assembly and test, the mobile device 100 can be packaged with the moveable contact 610 in the open position maintaining the electronic circuit 110 disconnected from the power source 120. When the user desires to use the mobile device 100, the user can apply a force with their finger or blunt object (e.g., a pen tip) to push on the moveable contact 610, displacing the restraining pins or tabs 622 into the closed position, connecting the electronic circuit 110 to the power source 120.

In accordance with some embodiments of the invention, the mobile device 100 can be encapsulated in a flexible and/or stretchable skin that protects the electronic circuit 110, the power source 120 and the switch 600 from the environment. In accordance with some embodiments of the invention, a small flat element can be positioned over the moveable contact 610 to concentrate a pressure or force applied to the surface of the mobile device 100 on the moveable contact 610 to make it easier to manipulate the moveable contact into the closed position. The outer surface of the mobile device 100 can include marking or indicia that indicates where to apply the force to move the moveable contact to the closed position. In accordance with some embodiments of the invention, the restraining pins or tabs 622 can be angled or positioned off-center to adjust the pressure or force needed to displace them in order to close the moveable contact 610 (e.g., decreasing the angle from perpendicular with respect to the contact surface of the moveable contact 610 will reduce the force needed to displace the restraining pins or tabs 622).

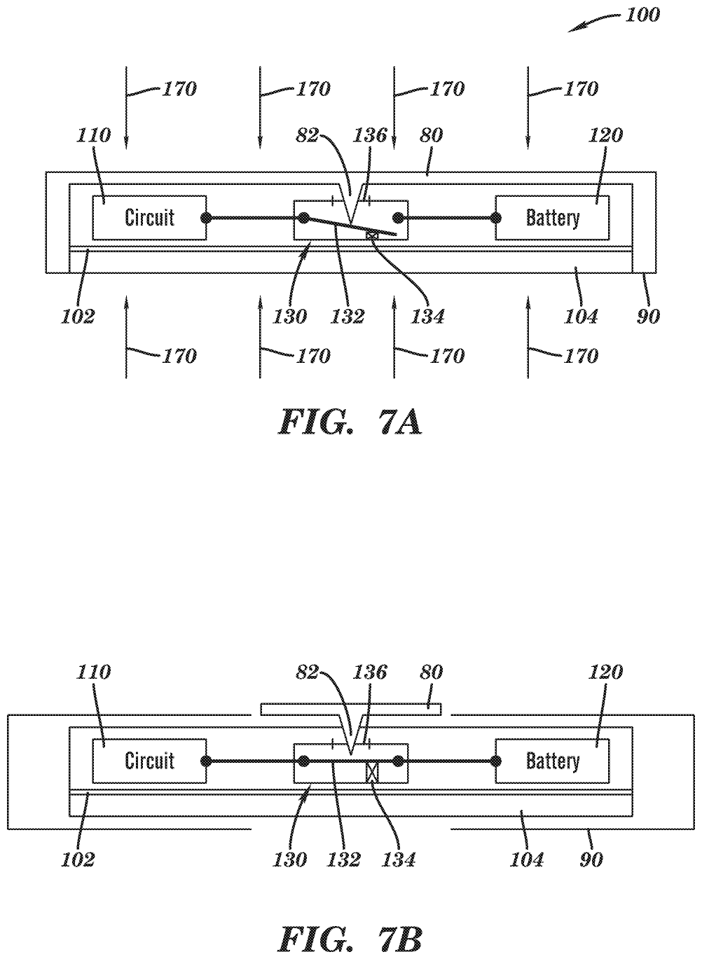

FIGS. 7A and 7B show diagrammatic views of a mobile device 100 in accordance with some embodiments of the invention. The mobile device 100 includes an electronic circuit 110 connected to a power source 120 (e.g., a battery) by a mechanical switch 130. The electronic circuit 110 that controls the operation of the mobile device can include, for example, a computer microprocessor and associated memory, and one or more sensors or actuators or radios or information display elements (e.g., a display screen, alpha numerical display or individual lights). The mechanical switch 130 can include a spring 134 that biases a moveable contact 132 of the switch into the closed position and a hole or other feature 136 that enables manipulation (e.g., via a pin, probe or other protruding feature) of the moveable contact 132 to open the switch 130. The mobile device 100 can also include one or more encapsulation layers or a housing or enclosure 108. The mobile device 100 can further include an adhesive layer 102 that can be used to adhere the device to a surface, such as the surface of an object or the skin of a person or animal. To protect the adhesive layer 102 prior to use, the mobile device 100 can include a liner 104 that covers the adhesive layer 102 while the mobile device 100 is in its packaging 90. The packaging 90 can be fully or partially evacuated and include a packaging insert element 80 that includes a feature 82 (e.g., a pin or probe) that projects through the hole 136 in the switch 130 to move the moveable contact 132 into the open position as long as the packaging 90 is sealed. In the sealed state, the air pressure 170 outside the package applies a pressure on the packaging 90 and the packaging insert 80 sufficient to apply pressure on the moveable contact 132 to maintain the switch 130 in the open position against the spring 134 and to keep the electronic circuit 110 disconnected from the power source 120 for shipment and storage. In accordance with some embodiments of the invention, the switch can be enclosed by a housing such that the insert can apply pressure on the switch but when the insert is removed, under normal use conditions, the housing prevents or limits the ability of a foreign object from applying pressure to the switch. For example, the housing can have a very small opening that provides access to the switch 130 or a spring loaded trap door can be provided. Alternatively, a latching circuit can be provided, such that once the mechanical switch 130 is closed, the latching circuit maintains the connection between the power source and the electronic circuit in the event a foreign object inadvertently applies pressure on the switch 130.

In operation, the mobile device 100 can be packaged in an evacuated sealed package 90 for shipment and storage. To prepare the device for use, the user opens the package 90 and removes the device 100. Upon opening the evacuated packaging 90, the pressure becomes equalized and packaging insert element 80 is no longer able to maintain pressure on the switch 130 and as a result, spring 132 moves the moveable contact 134 from the open position to the closed position connecting the electronic circuit 110 to the power source 120 to begin operation as shown in FIG. 7B.

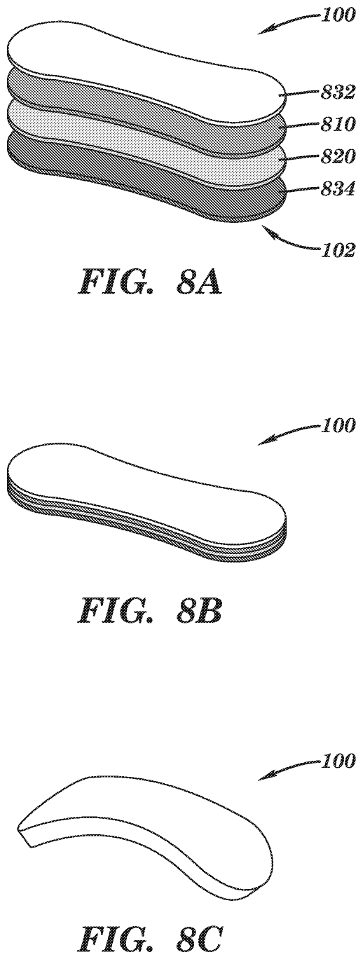

FIGS. 8A, 8B and 8C show diagrammatic views of a mobile device 100 in accordance with some embodiments of the invention. The mobile device 100 includes an electronic circuit 110 connected to a power source 120 (e.g., a battery) by a switch 130. The electronic circuit 110, and optionally, the power source 120 and the switch 130 can be mounted on a printed circuit board 810. The printed circuit board 810 can be a flexible printed circuit board and can be encapsulated between an upper encapsulation layer 832 (e.g., a plastic or elastic polymer, such as PDMS or silicone) and a lower encapsulation layer 834 (e.g., a plastic or elastic polymer, such as PDMS or silicone) or a housing or enclosure. The mobile device 100 can further include an adhesive layer 102 that can be used to adhere the device to a surface, such as the surface of an object or the skin of a person or animal. To protect the adhesive layer 102 prior to use, the mobile device 100 can include a liner 104 that covers the adhesive layer 102 while the mobile device 100 is in its packaging. In addition, a piezoelectric material can be included in a layer 820 that is positioned between the printed circuit board layer 810 and either of the upper encapsulation layer 832 and the lower encapsulation layer 834. The piezoelectric material layer 820 can be electrically connected to the switch 130 such that when the piezoelectric material is bent or compressed as shown in FIG. 8C, it generates an electric charge that operates the switch 130 connecting the electric circuit 110 to the power source 120. In accordance with some embodiments of the invention, the switch 130 can include a latching regulator that is maintained in the open position for shipment and storage, and becomes closed in response to receiving an electric charge from the piezoelectric material 820 to connect the electronic circuit 110 to the power source 120.

In operation, the mobile device 100 can be packaged with a stiffener or in a rigid package maintaining the mobile device in its nominal flat state. In preparation for use, the user opens the package and removes the mobile device 100 and then bends or flexes or stretches the mobile device 100 as shown in FIG. 8C causing the piezoelectric material 820 to generate an electric charge that operates the switch 130 connecting the electronic circuit 110 to the power source 120. For example, where the mobile device 100 includes an adhesive layer 102, the act of bending the mobile device 100 to remove the liner 104 can cause the piezoelectric material 820 to generate an electric charge sufficient to operate the switch 130.

While the various embodiments of the invention illustrate a switch or contacts providing a single connection between the electronic circuit 110 and the power source 120, each mobile device 100 can include multiple connections between one or more power sources 120 and various parts of the electronic circuit 110. Thus, for example, to provide improved isolation of a power source 120 during shipment and storage, two connections can be controlled using either two switches 130 or a double pole switch, which connect both the power and ground (or common) terminals of the power source 120 to the electronic circuit 110.

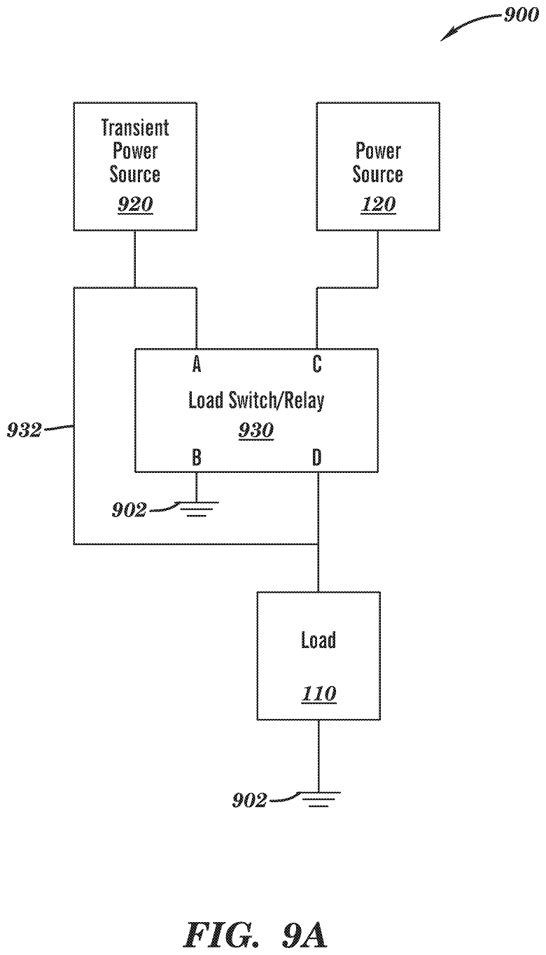

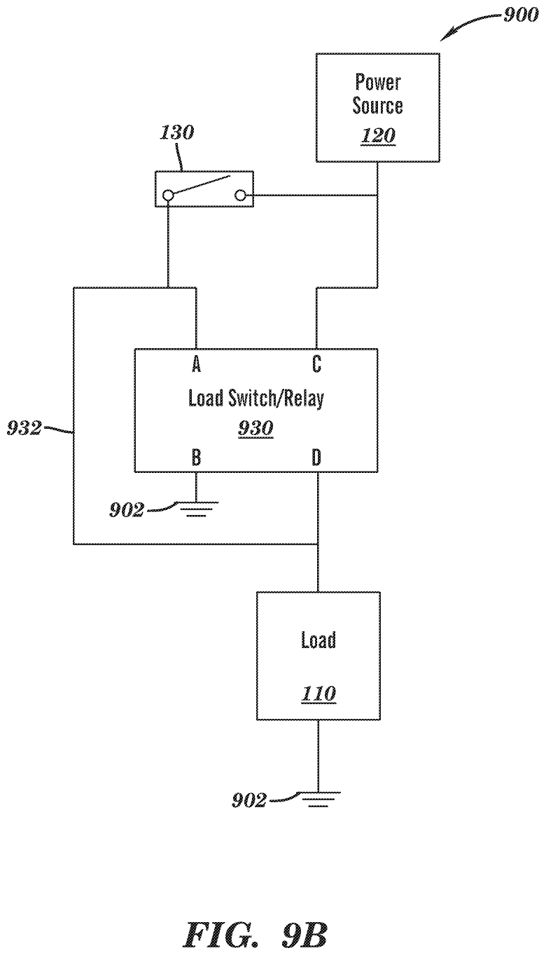

FIGS. 9A and 9B show diagrammatic views of a latching circuit according to some embodiments of the invention. The latching circuit 900 can be used to connect the main power source or battery 120 to the electronic circuit 110 of any of the mobile devices 100 described herein. In accordance with some embodiments of the invention, the latching circuit 900 includes a load switch or relay 930 having a control connections A and B, and load connections C and D. Control connections A and B can be used to control a switch that connects the load connection C to load connection D. Once the power source 120 is connected to the load 110, the power can also be connected through connection 932 to control connection A to latch the load switch or relay 930 in the closed position maintaining the connection of the power source 120 to the load circuit 110, until the power source 120 is exhausted.

As shown in FIG. 9A, the latching circuit 900 can be connected to a transient power source 920, such piezo electric material layer 820. In this configuration, when the transient power source 920 generates enough power through control connections A and B to activate the load switch or relay 930 and connect the power source 120 through load connections C and D to power up the load circuit 110. In addition, connection 932 latches the load switch or relay 930, by connecting the power source 120 to the control connection A such that after the transient power source 920 stops producing power, power from the power source 120 also powers the control connection A and B to maintain the load connection C and D in the closed position until the power source 120 is exhausted.

As shown in FIG. 9B, the latching circuit 900 can include a switch 130 (such as a momentary switch) that connects the power source 120 to control connection A. In this configuration, when the momentary switch 130 is closed, power from power source 120 is connected through control connections A and B to activate the load switch or relay 930 and connect the power source 120 through load connections C and D to power up the load circuit 110. In addition, connection 932 latches the load switch or relay 930, by connecting the power source 120 to control connection A such that after the momentary switch 130 is released (and stops connecting power to the control connection A), power from the power source 120 also powers the control connection A and B to maintain the load connection C and D in the closed position until the power source 120 is exhausted. This latching circuit 900 can be incorporated into the various embodiments of the invention, including those of FIGS. 1A and 1B, 2A and 2B, 3A and 3B, 4A and 4B, 5A and 5B, 6A-C, and 7A and 7B to disable switch 130 to prevent inadvertent contact, outside magnetic fields or vibration from opening the switch 130 and disconnecting the battery.

Other embodiments are within the scope and spirit of the invention. For example, due to the nature of software, functions described above can be implemented using software, hardware, firmware, hardwiring, or combinations of any of these. Features implementing functions may also be physically located at various positions, including being distributed such that portions of functions are implemented at different physical locations.

Further, while the description above refers to the invention, the description may include more than one invention.

What is claimed is:

1. A mobile device comprising;
an electronic circuit connected through a switch to a power source;
an adhesive layer connected between the electronic circuit and a protective liner;
wherein the switch is a normally closed switch and is held in an open position by a portion of the protective liner and whereby upon removal of the protective liner, the switch becomes closed connecting the electronic circuit to the power source.

2. The mobile device according to claim 1 wherein the switch is a normally closed magnetic reed switch and the protective liner includes a magnetic element adjacent to the magnetic reed switch that maintains the magnetic reed switch in the open position when the protective liner is coupled to the adhesive layer and upon removal of the protective liner, the magnetic element is moved from the switch causing the switch to become closed.

3. The mobile device according to claim 1 wherein the switch includes a set of contacts and the protective liner includes an insulating tab coupled to the protective liner and positioned between the set of contacts such that the switch is maintained in the open position when the protective liner is coupled to the adhesive layer and upon removal of the protective liner, the insulating tab removed from between the contacts of the switch causing the switch to become closed.

4. The mobile device according to claim 1 wherein the electronic circuit includes a microprocessor and associated memory.

5. The mobile device according to claim 1 wherein the electronic circuit includes at least one sensor.

6. The mobile device according to claim 1 wherein the electronic circuit includes at least one actuator.

7. The mobile device according to claim 1 wherein the power source includes a rechargeable battery.

8. The mobile device according to claim 1 wherein the electronic circuit is flexible and mounted on a flexible substrate.

9. A mobile device comprising;
an electronic circuit connected through a switch to a power source;
wherein the switch is an optical switch having an optical sensor such that the switch is closed when the optical sensor is exposed to light and the switch is closed when the optical sensor is blocked from exposure to light; and
mobile device packaging, including at least an opaque portion that blocks the optical sensor from exposure to light when the mobile device is positioned in the mobile device packaging, keeping the switch open while the switch is positioned in the mobile device packaging and wherein the switch closes when mobile device is removed from the mobile device packaging and the optical sensor is exposed to light.

10. The mobile device according to claim 9 wherein the electronic circuit includes a microprocessor and associated memory.

11. The mobile device according to claim 9 wherein the electronic circuit includes at least one sensor.

12. The mobile device according to claim 9 wherein the electronic circuit includes at least one actuator.

13. The mobile device according to claim 9 wherein the power source includes a rechargeable battery.

14. The mobile device according to claim 9 further comprising an adhesive layer connected between the electronic circuit and a protective liner;

15. The mobile device according to claim 9 wherein the electronic circuit is flexible and mounted on a flexible substrate.

16. A mobile device comprising;
an electronic circuit connected through a switch to a power source;
mobile device packaging enclosing the switch in an evacuated space;
wherein the switch is a normally closed switch and is held in an open position by a packing insert that applies a pressure on the switch to maintain the switch in the open position, and wherein when the mobile device packaging is opened, the pressure is removed and the switch closes connecting the electronic circuit to the power source.

17. The mobile device according to claim 16 wherein the electronic circuit includes a microprocessor and associated memory.

18. The mobile device according to claim 16 wherein the electronic circuit includes at least one sensor.

19. The mobile device according to claim 16 wherein the electronic circuit includes at least one actuator.

20. The mobile device according to claim 16 wherein the power source includes a rechargeable battery.

21. The mobile device according to claim 16 further comprising an adhesive layer connected between the electronic circuit and a protective liner;

22. The mobile device according to claim 16 wherein the electronic circuit is flexible and mounted on a flexible substrate.

23. A mobile device comprising;
an electronic circuit connected through a switch to a power source;
wherein the switch includes at least one moveable contact connected one of the electronic circuit and the power source, and a second contact connected to the other of the electronic circuit and the power source; and
wherein the switch includes at least one restraining element obstructing the movement of the at least one moveable contact from contacting the second contact, such that an application of force on the moveable contact moves the restraining element from obstructing the moveable contact and the moveable contact contacts the second contact to connect the electronic circuit to the power source.

24. The mobile device according to claim 23 wherein the at least one restraining element is flexible and the at least one restraining element flexes to move from obstructing the moveable contact.

25. The mobile device according to claim 23 wherein the at least one restraining element bends when the at least one restraining element is moved from obstructing the moveable contact.

26. The mobile device according to claim 23 wherein the at least one restraining element breaks when the at least one restraining element is moved from obstructing the moveable contact.
